(19) United States
(12) Patent Application Publication
(10) Pub. No.: US 2020/0096876 A1
(43) Pub. Date: Mar. 26, 2020

(54) Dose Map Optimization for Mask Making

(71) Applicant: ASML US, LLC f/k/a ASML US, INC., Chandler, AZ (US)

(72) Inventors: Jie Lin, San Jose, CA (US); Jiangwei Li, San Jose, CA (US); Song Lan, San Jose, CA (US); Ke Zhao, San Jose, CA (US); Jihui Huang, San Jose, CA (US)

(21) Appl. No.: 16/141,197

(22) Filed: Sep. 25, 2018

(51) Int. Cl. G03F 7/20; G03F 1/78

(52) U.S. Cl. CPC G03F 7/70558; G03F 7/70383; G03F 1/78

(57) ABSTRACT

A method and a non-transitory computer-readable storage medium for optimizing a dose map for a multi-beam mask writer includes simulating, by a processor, a substrate pattern based on a design pattern and the dose map associated with the design pattern, and updating a value of the dose map based on a comparison between the substrate pattern and the design pattern. An apparatus for optimizing a dose map for a multi-beam mask writer includes a processor and a memory coupled to the processor configured to store instructions to simulate a substrate pattern based on a design pattern and the dose map associated with the design pattern, and update a value of the dose map based on a comparison between the substrate pattern and the design pattern.

### TECHNICAL FIELD

This disclosure relates to mask making for manufacturing integrated circuits (ICs). More specifically, this disclosure relates to optimization of dose maps for mask making using a multi-beam mask writer.

### BACKGROUND

In semiconductor manufacturing, charged particle beams have been widely used to make high-precision masks. For example, mask makers (or “mask writers”) can use electron beams (“e-beams” or simply “beams”) to transfer design patterns onto masks (referred to as “mask patterns”). The mask patterns are transferred onto a substrate (e.g., a wafer) by a lithography process. The substrate with transferred patterns (referred to as “substrate patterns”) can be treated by following mechanical and chemical processes for manufacturing ICs.

E-beam mask writers can shoot electrons in shots for mask writing. A multi-beam e-beam mask writer can control the energy of the e-beam shots by using a dose map. The dose map can include information of energy values for different locations of the mask. Before application, the dose map can be optimized based on various factors (e.g., parameters of the mask writing process or the lithography process) to enhance fidelity of the substrate patterns to the design patterns. However, due to the increasing complexity of IC designs, the optimization of the dose maps faces challenges in efficiency and precision.

### SUMMARY

Disclosed herein are methods, apparatuses, and systems for optimizing a dose map for a multi-beam mask maker.

In an aspect, a method for optimizing a dose map for a multi-beam mask writer is disclosed. The method includes simulating, by a processor, a substrate pattern based on a design pattern and the dose map associated with the design pattern, and updating a value of the dose map based on a comparison between the substrate pattern and the design pattern.

In another aspect, an apparatus for optimizing a dose map for a multi-beam mask writer is disclosed. The apparatus includes a processor and a memory coupled to the processor. The memory is configured to store instructions which when executed by the processor become operational with the processor to simulate a substrate pattern based on a design pattern and the dose map associated with the design pattern, and update a value of the dose map based on a comparison between the substrate pattern and the design pattern.

In another aspect, a non-transitory computer-readable storage medium is disclosed. The non-transitory computer-readable storage medium includes instructions for optimizing a dose map for a multi-beam mask writer, which instructions when executed by a processor become operational with the processor to simulate a substrate pattern based on a design pattern and the dose map associated with the design pattern, and update a value of the dose map based on a comparison between the substrate pattern and the design pattern.

### BRIEF DESCRIPTION OF THE DRAWINGS

The disclosure is best understood from the following detailed description when read in conjunction with the accompanying drawings. It is emphasized that, according to common practice, the various features of the drawings are not to scale. On the contrary, the dimensions of the various features are arbitrarily expanded or reduced for clarity.

FIG. 1 shows an example lithography system.

FIG. 2 is a diagram of an example apparatus for generating a dose map according to implementations of this disclosure.

FIG. 3 is a flowchart of an example process for optimizing a dose map according to implementations of this disclosure.

FIG. 4 is a flowchart of an example process for simulating the substrate pattern according to implementations of this disclosure.

FIG. 5 is a flowchart of another example process for optimizing the dose map according to implementations of this disclosure.

### DETAILED DESCRIPTION

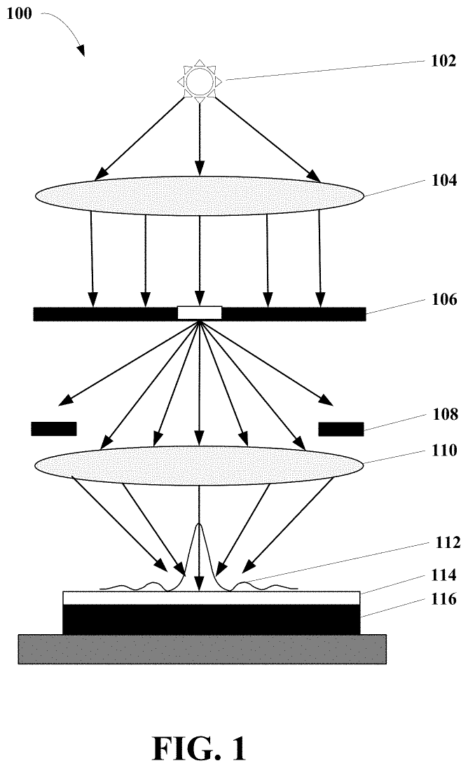

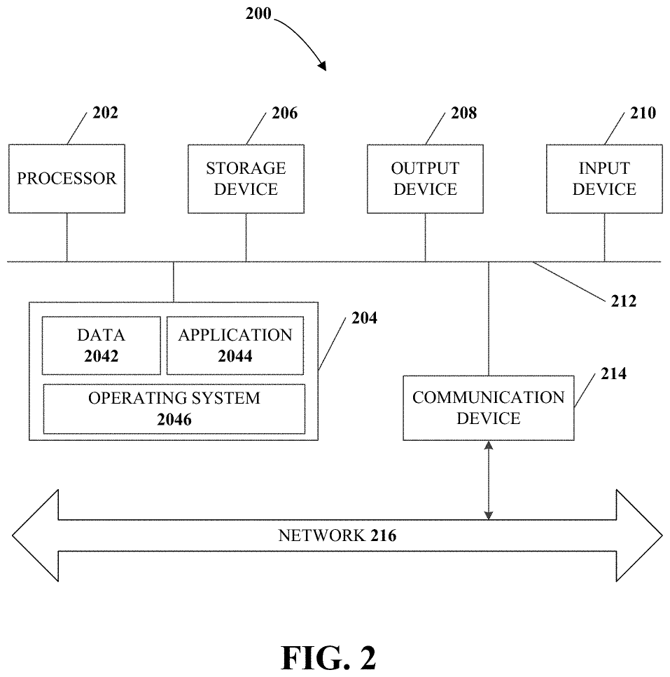

FIG. 1 shows an example lithography system 100. The light source 102 emits light that passes through a lens system 104 (e.g., a condenser lens system). The lens system 104 can transform the light as collinear. The collinear light illuminates a mask 106. The mask 106 can include patterns or shapes (referred to as “mask patterns”) representing desired shapes to be transferred onto a substrate (e.g., a silicon wafer). The material (e.g., quartz) of the mask 106 can be made to have different transmittances in different regions to represent the mask patterns. The light passing through the mask 106 carries the information of the mask patterns, which can form an image near the surface of a downstream side of the mask 106, which can be referred to as a “mask image.” After passing through an aperture 108 and an objective lens system 110, the mask image can be focused to form an aerial image 112 (represented as intensity distributions in FIG. 2) above a photoresist 114 coated upon a substrate 116. The incident light can expose regions of the photoresist 114 that modify their chemical properties. The modified photoresist 114 can be removed by applying a chemical solution (referred to as a “developer”) to the exposed regions of the photoresist 114, which exposes regions of the substrate underneath. The exposed regions of the substrate 116 can be etched (e.g., by an acid), while the unexposed regions of the substrate 116 can be protected by the unmodified regions of the photoresist 114. After the etching, the unmodified regions of the photoresist 114 can be removed by a chemical (referred to as a “resist stripper”), after which the mask patterns are transferred to the substrate (referred to as “substrate patterns”).

The mask 106 can be used in optical lithography (referred to as an “optical mask”). A mask writing process can convert design patterns (e.g., including polygons) into the mask patterns. During the mask writing process, the design patterns can be transferred onto a photoresist layer of a mask blank (e.g., a quartz substrate covered with a layer of chromium) using a light beam (e.g., in a laser writer) or an e-beam (e.g., in an e-beam writer). The beam can be controlled to move across the surface of the photoresist layer in a predetermined scan manner (e.g., a raster scan manner). The photoresist on the mask can be modified. In a process similar to developing, etching, and resist stripping, the chromium layer can be etched to have the transferred design patterns that are able to transmit light.

Optical proximity correction (referred to as “OPC”) technique is a resolution enhancement technique (referred to as “RET”) used to improve the fidelity of the substrate patterns during pattern transfer. Dimensions of the mask patterns are small. Due to diffraction of light, the mask image can be different from the design patterns, which can be propagated to the aerial image. In addition, due to non-uniformity of the developing and etching process, the fidelity of the substrate patterns can be further deteriorated. OPC can compensate for such fidelity deterioration of pattern transfer due to optical (e.g., diffraction), physical, and chemical effects. OPC can modify the polygons of the design patterns, such as by lengthening an edge, displacing an edge (referred to as “edge-biasing”), creating serifs at corners, or adding sub-resolution assistant features (SRAF) to the design patterns.

Single-beam mask writers (e.g., single variable shaped beam mask writers, or single-beam VSB e-beam writers) are widely used in mask writing. To ensure fidelity of substrate patterns, manufacturers can apply RETs (e.g., OPC) on IC design data (e.g., in a Graphic Database System or GDS data format) to generate post-RET (e.g., post-OPC) design data. Based on geometric patterns included in the post-OPC design data, mask shops can make the masks using a mask writer. For single-beam mask writers, the OPC typically generates Manhattan geometric shapes (e.g., polygons), which only include line segments in 0° and 90°.

As sizes of wafer pattern shrink, more aggressive OPC techniques can be used to enhance wafer pattern fidelity. Such more aggressive OPC techniques can generate curved mask shapes or curvilinear mask shapes (i.e., non-Manhattan shapes), but can be cumbersome. It can also increase complexity of post-OPC mask data. Due to increasing complexity of the post-OPC design data, multi-beam mask writers have become more popular in the mask making industry. Compared to single-beam mask writers, multi-beam e-beam mask writers can print more flexible shapes on a mask. By using more flexible shapes on the mask, fidelity of the patterns on wafer can be enhanced. For multi-beam mask writing, the geometric patterns defined in the post-OPC design data are converted to bitmaps via a rasterization process. Based on the bitmap, a dose map can be generated for the multi-beam mask writers. The term “dose” herein refers to an amount of energy applied to a substrate area upon exposure to an energy source (e.g., an ultraviolet or UV source, a deep ultraviolet or DUV source, an extreme ultraviolet or EUV source, or an e-beam source). For ease of explanation without causing ambiguity, the e-beam source is described as the energy source hereinafter unless explicitly stated otherwise. The dose can depend on an intensity of a shot and a time interval of the shot (referred to as “exposure time”). The dose map can include dose information (e.g., exposure passes of the e-beams) for the mask writer to shoot the e-beams in designated exposures on locations of a mask blank. Based on the dose map, the multi-beam mask writers can transfer the design patterns onto the mask blank as mask patterns.

The optimization of the dose map based on post-OPC design data can use a lot of computation resources. Due to increasing complexity of the post-OPC design data, the aforementioned optimization process is becoming less efficient for multi-beam mask writing. Further, OPC-based mask pattern generation typically starts from dissected design patterns (e.g., polygons) to perform shape optimization. Therefore, the OPC-optimized mask patterns can bear a certain level of similarity to the design patterns. For example, if the design patterns are Manhattan shapes, the OPC-optimized mask patterns can be more complicated Manhattan shapes. Because of inherent limitations in angles, curved geometric shapes cannot be generated using the Manhattan shapes without consuming high computation resources. Thus, substrate pattern fidelity can be limited.

This disclosure proposes methods, apparatuses, and systems for optimizing a dose map without post-OPC design data generation and the rasterization. The optimized dose map can be directly used by multi-beam mask writers. The methods and systems disclosed herein can generate and process more flexible mask shapes (e.g., curvilinear mask shapes) in a natural and inherent way, with high efficiency in computation resources. By using the more flexible mask shapes, inherent geometric limitations carried by the Manhattan shapes can be removed, more forms of substrate patterns can be generated, and fidelity of the substrate patterns can be improved.

In some implementations, a dose map (e.g., previously determined or generated by other methods) associated with a design pattern can be received. For example, the dose map can be predetermined based on the design pattern and parameters of the manufacturing process (referred to as “process parameters”). The dose map can be used by a simulation process to simulate a substrate pattern. The simulation process can be used to simulate the multi-beam mask making (referred to as “mask-making simulation”) that uses the dose map. Based on the dose map, the mask-making simulation can be used to simulate transforming the design pattern into mask patterns on a mask blank. Based on the simulated mask patterns, the simulation process can further simulate transforming the mask patterns into substrate patterns on a substrate (referred to as “substrate-manufacturing simulation” or “wafer-manufacturing simulation”). The substrate patterns can be compared with the design patterns to determine a difference. The difference can be used as a gauge for optimizing the dose map. For example, to minimize the difference, values of parameters associated with mask-making (e.g., values of parameters of the dose map) can be updated for re-simulating the substrate patterns and re-calculating the difference. This process can be iterated until the difference between the substrate patterns and the design patterns is less than a threshold when the dose map can be considered as having been optimized.

The disclosed methods, apparatuses, and systems can increase efficiency and accuracy in dose map optimization for multi-beam mask writing. By using the dose map optimized in accordance with the disclosed methods, the manufactured substrate patterns can achieve high fidelity to the design patterns. In addition, besides geometric features, the disclosed methods, apparatuses, and systems can further include information generated during the dose map optimization, such as mask error enhancement factor (MEEF). Such information can greatly improve substrate pattern fidelity and is typically lost in the OPC-based dose map optimization. For example, mask making errors can be controlled in accordance with a MEEF of a pattern. For patterns with a large MEEF, mask making errors can be controlled more tightly, such as by increasing an e-beam dose.

FIG. 2 is a diagram of an example apparatus 200 for generating a dose map according to implementations of this disclosure. The apparatus 200 can include any number of any configurations of computing devices, such as a microcomputer, a mainframe computer, a supercomputer, a general-purpose computer, a special-purpose/dedicated computer, an integrated computer, a database computer, a remote server computer, a personal computer, or a computing service provided by a computing service provider, for example, a web host, or a cloud service provider. In some implementations, the computing devices can be implemented in the form of multiple groups of computers that are at different geographic locations and can communicate with one another, such as by a network. While certain operations can be shared by multiple computers, in some implementations, different computers can be assigned to different operations. In some implementations, the apparatus 200 can be implemented using general-purpose computers/processors with a computer program that, when executed, carries out any of the respective methods, algorithms and/or instructions described herein. In addition, for example, special-purpose computers/processors, which can contain specialized hardware for carrying out any of the methods, algorithms, or instructions described herein, can be utilized.

The apparatus 200 can have an internal configuration of hardware including a processor 202 and a memory 204. The processor 202 can be any type of device capable of manipulating or processing information. In some implementations, the processor 202 can include a central processing unit (CPU). In some implementations, the processor 202 can include a graphics processor (e.g., a graphics processing unit or GPU). For example, the GPU can provide additional graphical processing capability for at least one of pattern rendering, dose map optimization, mask-making simulation, and substrate-manufacturing simulation. Although the examples herein are described with a single processor as shown, advantages in speed and efficiency can be achieved using multiple processors. For example, the processor 202 can be distributed across multiple machines or devices (in some cases, each machine or device can have multiple processors) that can be coupled directly or connected to a network. The memory 204 can be any transitory or non-transitory device capable of storing codes and data that can be accessed by the processor (e.g., via a bus). For example, the memory 204 can be accessed by the processor 202 via a bus 212. Although a single bus is shown in the apparatus 200, multiple buses can be utilized. The memory 204 herein can be a random-access memory device (RAM), a read-only memory device (ROM), an optical/magnetic disc, a hard drive, a solid-state drive, a flash drive, a security digital (SD) card, a memory stick, a compact flash (CF) card, or any combination of any suitable types of storage devices. In some implementations, the memory 204 (e.g., a network-based or cloud-based memory) can be distributed across multiple machines or devices. The memory 204 can store data 2042, an operating system 2046, and an application 2044. The data 2042 can be any data for processing (e.g., computerized data files or database records). The application 2044 can include programs that permit the processor 202 to implement instructions to perform functions described in this disclosure. For example, when the application 2044 is run, a set of algorithms, processes, or steps can be executed for dose map creation, dose map optimization, mask-making process simulation, and substrate-manufacturing simulation.

In some implementations, in addition to the processor 202 and the memory 204, the apparatus 200 can include a secondary (e.g., additional or external) storage device 206. The secondary storage device 206 can provide additional storage capacity for high processing needs. The secondary storage device 206 can be a storage device in the form of any suitable transitory or non-transitory computer-readable media, such as a memory card, a hard disk drive, a solid-state drive, a flash drive, or an optical drive. Further, the secondary storage device 206 can be a component of the apparatus 200 or can be a shared device that can be accessed via a network. In some implementations, the application 2044 can be stored in whole or in part in the secondary storage device 206 and loaded into the memory 204. For example, the secondary storage device 206 can be used for a database.

In some implementations, in addition to the processor 202 and the memory 204, the apparatus 200 can include an output device 208. The output device 208 can be, for example, a display coupled to the apparatus 200 for displaying graphics data. If the output device 208 is a display, for example, it can be a liquid crystal display (LCD), a cathode-ray tube (CRT) display, or any other output device capable of providing a visible output to an individual. The output device 208 can also be any device transmitting visual, acoustic, or tactile signals to a user, such as a touch-sensitive device (e.g., a touchscreen), a speaker, an earphone, a light-emitting diode (LED) indicator, or a vibration motor. In some implementations, the output device 208 can also function as an input device (e.g., a touch screen display configured to receive touch-based input). For example, the output device 208 can include a display that can display images, simulation results, simulation parameters, or a combination thereof. The output device 208 can enable a user (e.g., a mask design engineer) to assess the current status of the optimization of the dose map.

In some implementations, the output device 208 can also function as a communication device for transmitting signals and/or data. For example, the output device 208 can include a wired means for transmitting signals or data from the apparatus 200 to another device. For another example, the output device 208 can include a wireless transmitter using a protocol compatible with a wireless receiver to transmit signals from the apparatus 200 to another device.

In some implementations, in addition to the processor 202 and the memory 204, the apparatus 200 can include an input device 210. The input device 210 can be, for example, a keyboard, a numerical keypad, a mouse, a trackball, a microphone, a touch-sensitive device (e.g., a touchscreen), a sensor, or a gesture-sensitive input device. Any type of input device not requiring user intervention is also possible. For example, the input device 210 can be a communication device, such as a wireless receiver operating according to any wireless protocol for receiving signals. The input device 210 can output signals or data, indicative of the inputs, to the apparatus 200, for example, via the bus 212. For example, a user or operator can provide simulation-related information to the apparatus 200 via the input device 210. For another example, the input device 210 can also be an interface (e.g., a scanner) that can enable a user to provide images to the apparatus 200 related to the design pattern of the mask.

In some implementations, in addition to the processor 202 and the memory 204, the apparatus 200 can optionally include a communication device 214 to communicate with another device. Optionally, the communication can occur via a network 216. The network 216 can include one or more communications networks of any suitable type in any combination, including, but not limited to, Bluetooth networks, infrared connections, near-field connections (NFC), wireless networks, wired networks, local area networks (LAN), wide area networks (WAN), virtual private networks (VPN), cellular data networks, or the Internet. The communication device 214 can be implemented in various ways, such as a transponder/transceiver device, a modem, a router, a gateway, a circuit, a chip, a wired network adapter, a wireless network adapter, a Bluetooth adapter, an infrared adapter, an NFC adapter, a cellular network chip, or any suitable type of device in any combination that can communicate with the network 216. For example, the communication device 214 can connect to a mask maker via the network 216 to send the generated or optimized dose map to a multi-beam mask writer. For another example, the communication device 214 can also be connected to another computing device including an Electronic Design Automation (EDA) tool that can generate a target substrate design based on one or more layers of the desired IC design. For another example, remote control instructions can be received by the communication device 214 from another computing device connected to the network 216 for remote control of the apparatus 200.

The apparatus 200 (and algorithms, methods, instructions, etc., stored thereon and/or executed thereby) can be implemented as hardware modules, such as, for example, intellectual property (IP) cores, application-specific integrated circuits (ASICs), programmable logic arrays, optical processors, programmable logic controllers, microcode, firmware, microcontrollers, servers, microprocessors, digital signal processors, or any other suitable circuit. Further, portions of the apparatus 200 do not necessarily have to be implemented in the same manner.

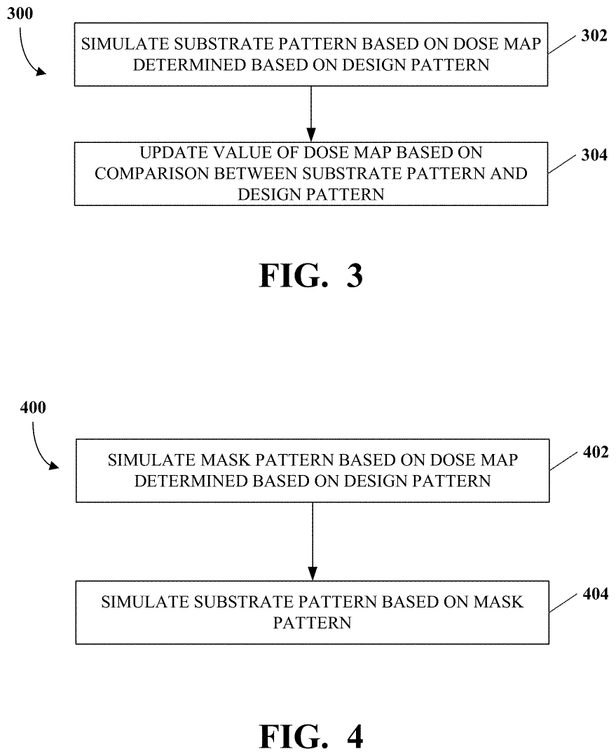

FIG. 3 is a flowchart of an example process 300 for optimizing a dose map according to implementations of this disclosure. The process 300 can be implemented in hardware or software. For example, the process 300 can be implemented in software stored as instructions and/or data in the memory 204 and executable by the processor 202 of the apparatus 200. For another example, the process 300 can be implemented in hardware as a specialized chip storing instructions executable by the specialized chip. The multi-beam mask writer can shoot multiple charged particle beams (e.g., in an array of e-beams to the order of a quarter-million) onto the mask blank in accordance with the dose map. It should be noted that the process 300 can also be implemented for other types of mask writers, such as a single-beam VSB mask writer.

At operation 302, a substrate pattern is simulated based on a design pattern and the dose map associated with the design pattern. As used herein, the term “substrate pattern” refers to a pattern on a surface of a substrate (e.g., a silicon wafer) that is transferred from the mask pattern through a lithography system (e.g., the lithography system 100). In some implementations, the substrate pattern can be a pattern in the aerial image 112. In some other implementations, the substrate pattern can be a pattern in an image simulated based on the aerial image 112 with additional simulations of chemical and/or physical processes (e.g., developing, etching, and/or resist stripping).

In some implementations, the design pattern and the dose map can be received (e.g., by the input device 210 of the apparatus 200). As used herein, the term “receive” can refer to receiving, inputting, acquiring, retrieving, obtaining, reading, accessing, collecting, or any action for inputting information or data in any manner. In some implementations, the dose map can be predetermined based on the design pattern (e.g., provided by a design house). The design pattern can include geometric features (e.g., dots, lines, spaces, triangles, rectangles, trapezoids, polygons, or any other geometric patterns or shapes) that form parts of the IC design. The design pattern can also include vias representing vertical interconnections of the IC design. In an implementation, the design pattern can include symbolic or vectorized data (e.g., GDS format data). In another implementation, the design pattern can include a pixelated image (e.g., a bitmap). For example, the design pattern can include an image created by the EDA tool.

In some implementations, the dose map can be determined by other methods or obtained from a previous manufacturing process. In some implementations, the dose map can include designated default values related or unrelated to actual manufacturing processes. In some implementations, the GDS data and/or the process parameters can be received together with the dose map.

At operation 304, a value of the dose map is updated based on a comparison between the substrate pattern and the design pattern. For example, the value of the dose map can include any combination of any number of a coordinate of an e-beam shot associated with the dose map (i.e., a coordinate of a location of the mask at which the e-beam writer shoots the e-beam shot), an intensity value of the e-beam shot, an exposure time of the e-beam shot, and an energy exposure value of the e-beam shot. The energy exposure value can be a product of the intensity value and the exposure time of the e-beam shot.

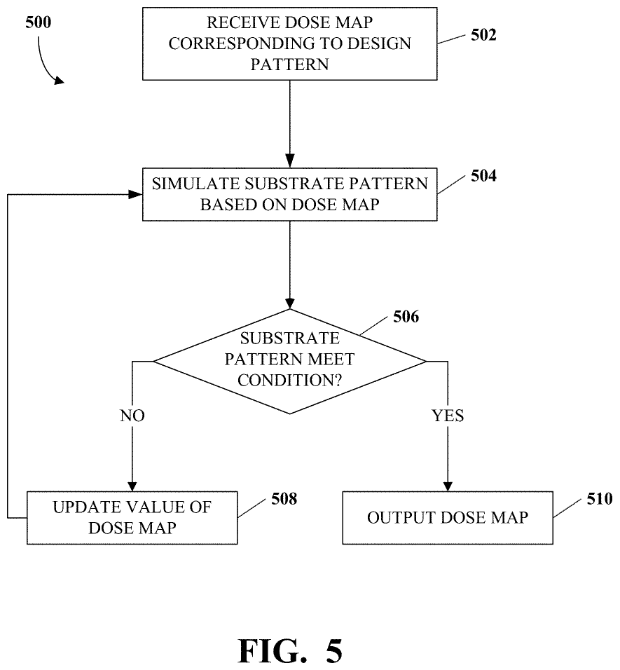

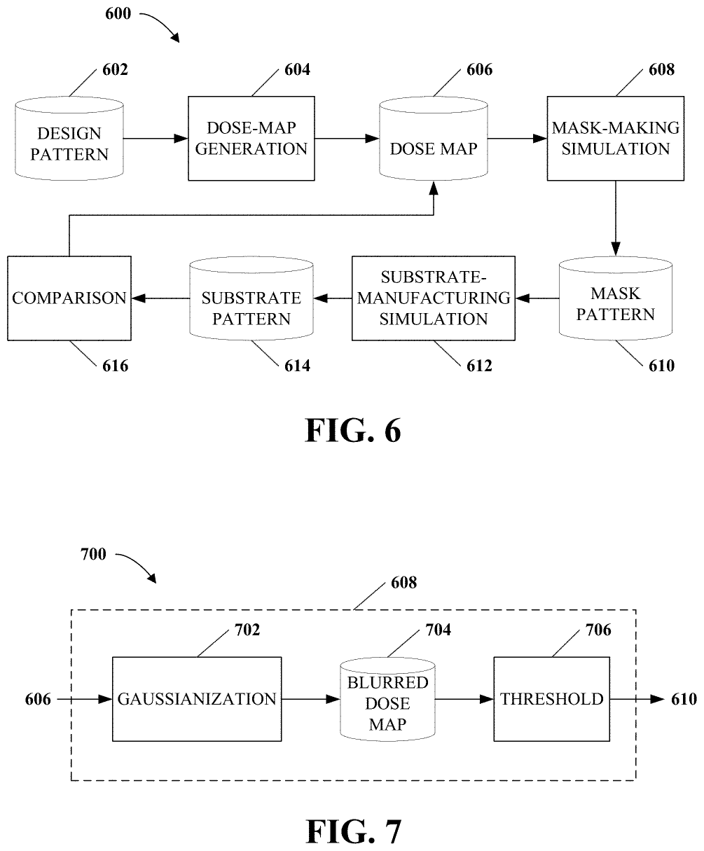

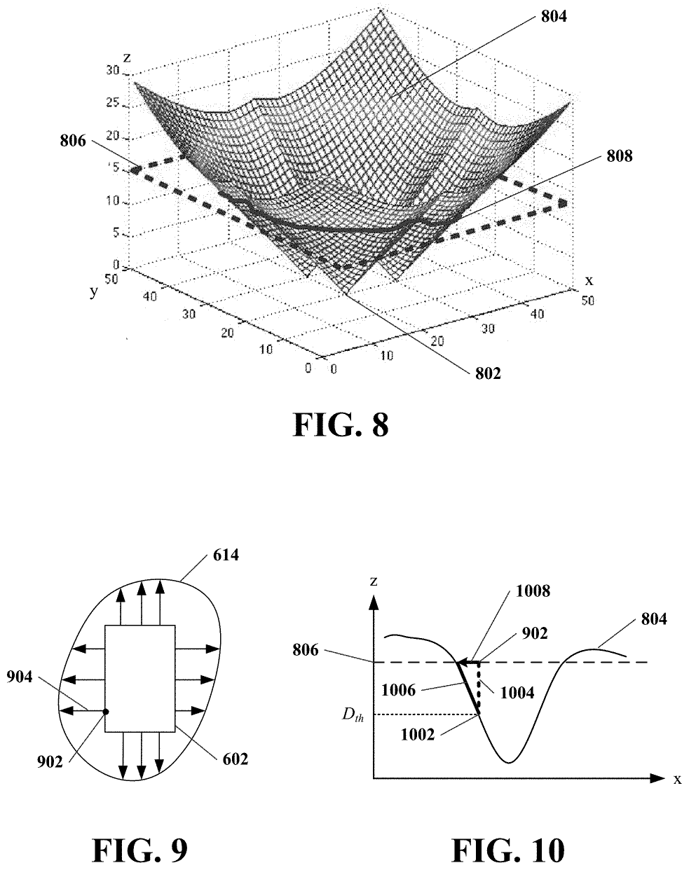

In some implementations, the comparison between the substrate pattern and the design pattern can be image-based. For example, an image of the design pattern (referred to as a “design pattern image”) can be superimposed with an image of the substrate pattern (referred to as a “substrate pattern image”) to determine a similarity value between corresponding geometric features (e.g., contours, edges, and/or corners) of the design pattern image and substrate pattern image. For example, the similarity value can be a value of a cost function. The cost function can be determined based on distances between points of the substrate pattern and respective corresponding points in the design pattern. The similarity value can indicate the quality of the simulated substrate pattern (e.g., the higher the similarity value, the greater the similarity between the substrate pattern and the design pattern, or vice versa). For example, when the similarity value is greater than or equal to a predetermined threshold, the substrate pattern is deemed as not similar to the design pattern, and the value of the dose map can be updated. When the similarity value is smaller than the predetermined threshold, the substrate pattern is deemed as similar to the design pattern, and the optimization of the dose map can be deemed as completed, in which case the dose map can be outputted for mask making. It should be noted that the boundary condition for making such determination is not limited to the aforementioned examples and can be modified or alternated without creative efforts, such as replacing the “greater than or equal to” and “smaller than” with “greater than” and “smaller than or equal to,” respectively. The details of the cost function will be set forth in FIG. 5 and its related descriptions.

It should be noted that the comparison between the substrate pattern and the design pattern can include other implementations that are not limited to a similarity value. The cost function can also be implemented based on other characteristics of the substrate pattern and the design pattern, not limited to the distances between their corresponding points. Further, the condition for determining when to update the value of the dose map can be implemented in various ways, which can be derived from this disclosure without creative effort.

In some implementations, the process 300 can be implemented as iterations. For example, the updated dose map can be used for simulating a new substrate pattern, and a new comparison can be performed between the new substrate pattern and the design pattern. The iteration can be repeated until a predetermined condition is met, such as the similarity value being smaller than the predetermined threshold.

FIG. 4 is a flowchart of an example process 400 for simulating the substrate pattern according to implementations of this disclosure. The process 400 can be an implementation of the operation 302 in FIG. 3. The process 400 can be implemented in hardware or software. For example, the process 400 can be implemented in software stored as instructions and/or data in the memory 204 and executable by the processor 202 of the apparatus 200. For another example, the process 400 can be implemented in hardware as a specialized chip storing instructions executable by itself.

At operation 402, a mask pattern is simulated based on the design pattern and the dose map. In other words, the operation 402 can perform the mask-making simulation. The mask-making simulation can use a mask-making model that simulates the mask pattern based on the design pattern and the dose map.

The mask-making model can be used to simulate physical, optical, and/or chemical interactions of a mask writing process. For example, the energy source can be simulated as an e-beam emitter. The energy of each e-beam can conform to a Gaussian distribution. Based on the dose map, one or more functions or functionals (referred to herein as “functions” for simplicity) can be implemented to simulate projecting the e-beam exposure onto a simulated mask blank. The functions can include an algorithm, an equation, or any relationship between the energy distribution of the e-beams at the e-beam emitter and the energy distribution of the e-beams on the surface of the mask blank. Chemical simulations can be performed for the mask blank to simulate development. The chemical simulations can also be performed to simulate etching of the developed mask blank and generate the mask pattern.

For example, assuming that the dose map is represented by D[i, j], where [i, j] represent the coordinates of a point on the mask blank and D represents a dose at a point [i, j], and assuming the design pattern is represented by a set of points {(dxₙ, dyₙ)}, the mask pattern can be determined using:

mxₙ=MXₙ[D[i, j]]

myₙ=MYₙ[D[i, j]] Eq. (1)

In Eq. (1), mxₙ and myₙ are coordinates of a point n (n=1, 2, 3, . . . ) of the mask pattern. The set {(mxₙ, myₙ)} is a set of points that can define a set of mask patterns. That is, by connecting the points in {(mxₙ, myₙ)}, one or more mask patterns (e.g., geometric shapes) can be generated. For example, (mxₙ, myₙ) can represent points in the mask that can let the light pass through. For another example, (mxₙ, myₙ) can represent points in the mask that can block the light. It should be noted that {(mxₙ, myₙ)} can be flexible mask shapes, such as curvilinear mask shapes.

MXₙ and MYₙ are functions that can be used to map the dose map to the coordinates of the point n. For example, the generation of {(mxₙ, myₙ)} can generally include two stages. In the first stage, a mask image (e.g., a pixelated mask image) can be generated from the dose map, such as by using:

MI[i′, j′]=MA[D[i, j]] Eq. (2)

In Eq. (2), MI [i′, j′] represents the mask image, where [i′, j′] represent the coordinates of a point on the mask image, and MA represents a mapping function. MA can be used to simulate the projection of the e-beam onto the mask blank in accordance with the dose map and the design pattern. In some implementations, MA can include a Gaussian convolution. For example, to determine MI[i′, j′], the Gaussian distribution of the e-beam can be convoluted with the dose D[i, j].

In the second stage, a first thresholding operation can be applied to MI [i′, j′] to determine {(mxₙ, myₙ)}. The first thresholding operation can be used to simulate the development etching and/or resist stripping. For example, a first threshold dose can be used such that, when the point n receives a dose exceeding or equal to the first threshold dose, the point n can be deemed as developed. When the point n receives a dose below the first threshold dose, the point n can be deemed as not developed.

MXₙ and MYₙ in Eq. (1) can be seen as a combination of MA and the first thresholding operation. It should be noted that, the mask image MI [i′, j′] can be a virtual image. That is, the combination of MA and the first thresholding operation can be a single operation (e.g., in an algorithm), and the MI [i′, j′] can be in a form of intermediate data and not actual generated image data.

In some implementations, optimization (e.g., rule-based optimization or model-based optimization) can be applied to pre-compensate for the optical distortions (e.g., aberrations, refractions, diffractions, and reflections) in the pattern transfer process. For example, SRAFs can be added to the mask pattern.

At operation 404, a substrate pattern is simulated based on the mask pattern. In other words, the operation 404 can perform the substrate-manufacturing simulation. The substrate-manufacturing simulation can be used to simulate a mask image using the mask pattern, and simulate the substrate pattern based on the mask image using a substrate-manufacturing model. The substrate pattern can be a pixelated image or a vectorized image.

In some implementations, the mask pattern {(mxₙ, myₙ)} can be used for simulating a mask image M[i, j] (e.g., a pixelated image or a vectorized image) that includes the geometric features of the mask pattern. In some implementations, the mask image M[i, j] can be pixelated. For example, the mask image can be a grayscale image, in which values of the pixels can be indicative of brightness or darkness. For another example, the mask image can be a binary image (e.g., a black-and-white image), in which the values of the pixels can be indicative of black (e.g., of a value 1) and white (e.g., of a value 1). For example, the white pixels can represent the etched area of the mask, and the black pixels can represent the non-etched area of the mask, or vice versa.

In some implementations, the mask image and the process parameters can be inputted to the substrate-manufacturing model for simulating the substrate pattern. The process parameters can depend on different semiconductor fabrication plants and/or different lithography machines. The substrate-manufacturing model can be used to simulate the physical, optical, and chemical interactions of a pattern transfer process. For example, an optical transfer function can be implemented to simulate transforming the mask image to an aerial image (e.g., the aerial image 112), and a chemical/physical simulation can be performed to transform the aerial image to the substrate pattern (referred to as a “resist process”). The process parameters can be inputted to the optical transfer function for simulating optical distortions and/or physical limitations (e.g., resolution loss in high-order diffractions) in the pattern transfer process. When conditions of the pattern transfer process change, parameters of the substrate-manufacturing model can also be adjusted accordingly. For example, parameters of the substrate-manufacturing model for a 28-nm node can be different from the parameters for a 10-nm node.

It should be noted that the methods, apparatuses, and systems disclosed herein have flexibility of using different kinds of substrate-manufacturing models depending on different circumstances. For example, when available, a substrate-manufacturing model that simulates many or all aspects of the IC manufacturing process (e.g., optical processes, aerial image formation, and resist image formation) can be used. When such substrate-manufacturing model is not available (e.g., during an early development stage of a new manufacturing process), a substrate-manufacturing model that mainly or only simulates optical processes can be used, as a tradeoff for investigating feasibility of the new manufacturing process. For another example, as the development progresses and substrate-manufacturing models with higher accuracy having become available, those substrate-manufacturing models can be used for the disclosed methods, apparatuses, and systems to improve performance.

For example, the substrate-manufacturing model can be represented as:

wxₘ=WXₘ[M[i ,j]]

wyₘ=WYₘ[M[i, j]] Eq. (3)

In Eq. (3), wxₘ and wyₘ are coordinates of a point m (m=1, 2, 3, . . . ) of the substrate pattern. The set {(wxₘ, wyₘ)} is a set of points that can define a set of substrate patterns. That is, by connecting the points in {(wxₘ, wyₘ)}, one or more substrate patterns (e.g., geometric shapes) can be generated. In some implementations, the interior of the substrate patterns can represent regions to be developed. In some implementations, the exterior of the substrate patterns can represent the regions to be developed. In some implementations, the substrate pattern {(wxₘ, wyₘ)} can be pixelated (e.g., a grayscale image or a binary image). For example, if the substrate pattern is a binary image, the white pixels can represent the etched area of the substrate, and the black pixels can represent the non-etched area of the substrate, or vice versa.

WXₘ and WYₘ are functions that can be used to map the mask image to the coordinates of the point m. For example, the generation of {(wxₘ, wyₘ)} can generally include two stages. In the first stage, a substrate image (e.g., a pixelated substrate image) can be generated from the mask image, such as by using:

WI[i″, j″]=WA[M[i, j]] Eq. (4)

In Eq. (4), WI[i″, j″] represents the substrate image, where [i″, j″] represent the coordinates of a point on the substrate image, and WA represents a mapping function. WA can be used to simulate the projection of the mask image onto the substrate. In some implementations, WA can include a transmission cross coefficient (TCC) kernel convolution and a Gaussian convolution. For example, the TCC-kernel convolution can be performed before or after the Gaussian convolution.

In the second stage, a second thresholding operation can be applied to WI/[i″, j″] to determine {(wxₘ, wyₘ)}. The second thresholding operation can be used to simulate the development, etching, and/or resist stripping. For example, a second threshold dose can be used such that, when the point m receives a dose exceeding or equal to the second threshold dose, the point m can be deemed as developed. When the point m receives a dose below the second threshold dose, the point m can be deemed as not developed.

WXₘ and WYₘ in Eq. (3) can be seen as a combination of WA and the second thresholding operation. It should be noted that, the substrate image WI/[i″, j″] can be a virtual image. That is, the combination of WA and the second thresholding operation can be a single operation (e.g., in an algorithm), and the WI[i″, j″] can be in a form of intermediate data and not actual generated image data.

As shown in FIGS. 3 and 4, the OPC is performed in neither the process 300 nor the process 400. Therefore, the post-OPC design data generation can be omitted, which can increase computation efficiency. In addition, by integrally applying the mask-making simulation and substrate-manufacturing simulation, intermediate information (e.g., MEEF) can be kept for the optimization of the dose map, which can increase optimization accuracy. Further, by directly using pixelated images (e.g., bitmaps) in the dose map optimization, the rasterization of the post-OPC data can be omitted, which can further increase computation efficiency. The optimized dose map can be directly used by a multi-beam mask writer.

FIG. 5 is a flowchart of an example process 500 for optimizing the dose map according to implementations of this disclosure. The process 500 can be implemented in hardware or software. For example, the process 500 can be implemented in software stored as instructions and/or data in the memory 204 and executable by the processor 202 of the apparatus 200. For another example, the process 500 can be implemented in hardware as a specialized chip storing instructions executable by itself.

At operation 502, a design pattern and a dose map are received. The dose map can be associated with the design pattern. In some implementations, the dose map can be predetermined based on the design pattern and one or more process parameters (e.g., provided by a semiconductor fabrication plant).

At operation 504, a substrate pattern is simulated based on the design pattern and the dose map. The operation 504 can be similar to the operation 302 in FIG. 3 and the operations 402-404 in FIG. 4.

At operation 506, it is determined whether the simulated substrate pattern meets a predetermined condition based on a comparison between the simulated substrate pattern and the design pattern. If the predetermined condition is not met, the process 500 proceeds to operation 508. Otherwise, the process 500 proceeds to operation 510.

For example, similar to the operation 304, a similarity value can be determined between the substrate pattern and the design pattern, and the predetermined condition can include a predetermined threshold. When the similarity value is below the predetermined threshold, the predetermined condition can be deemed as met (i.e., the substrate pattern can be determined to be similar to the design pattern). When the similarity value is greater than or equal to the predetermined threshold, the predetermined condition can be deemed as not met (i.e., the substrate pattern can be determined to be not similar to the design pattern).

In some implementations, the similarity value can be determined as a sum of absolute values of the distances between the corresponding geometric features of the design pattern and the substrate pattern. In some implementations, the similarity value can be determined using a cost function for the image-based comparison, in which the similarity value can also be referred to as a “cost.” For example, a cost C can be determined as:

$$C = {\sum }_{i}^{ } ( {( {dx}_{i} - {wx}_{i} )}^{2} + {( {dy}_{i} - {wy}_{i} )}^{2} ) \qquad Eq . ( 5 )$$

In Eq. (5), the index i runs over etched points (e.g., all etched points) in the substrate pattern (e.g., white pixels in the substrate pattern), (wxᵢ, wyᵢ) is a point of the substrate pattern, and (dxᵢ, dyᵢ) is a point of the design pattern (e.g., a point of a polygon) that has the closest distance to (wxᵢ, wyᵢ). In other words, in Eq. (5), C is determined as a sum of squares of the Euclidean distances between points of the substrate pattern and the respective corresponding points of the design pattern.

In some implementations, the cost can be determined based on other variables (e.g., process window conditions), such as, for example, a process window metric, an image log slope (“ILS”), an edge placement error (“EPE”), a mask error enhancement factor (“MEEF”), or any combination thereof. In some implementations, a total cost Cost can be determined as a weighted sum of a set of cost values:

$$Cost = {\sum }_{j} {weight}_{j} \cdot {C}_{j} \qquad Eq . ( 6 )$$

In Eq. (6), the index j runs over cost values determined based on different variables. Cᵢ is a cost determined based on a variable i, and weightᵢ is a weight designated for CᵢFor example, one of Cᵢ can include the C in Eq. (5). It should be noted that the similarity value can be determined in various ways and is not limited to the above examples.

At operation 508, when the predetermined condition is not met, a value of the dose map is updated, and the process 500 goes back to the operation 504. The operation 508 can be similar to the operation 304. The updated dose map can be used at the operation 504 to determine a new substrate pattern. The operations 504-508 can be iterated until the predetermined condition is met.

As shown in Eqs. (1)-(5), given any dose map D[i, j ], the cost C can be determined, and the operations 504-508 can be seen as an optimization process. In this optimization process, D[i, j] is the optimization variable, and C is the optimization object. That is, the optimization can adjust values of D[i, j] to minimize C, until C reaches a minimum value (e.g., its derivative is 0) or is smaller than the predetermined threshold (e.g., 0.5, 0.05, 0.001, or any small positive number).

To determine the minimum (e.g., a local minimum or a global minimum) value of C, the values of D[i, j] can be adjusted until:

$$\frac{\partial C}{\partial D [ i , j ]} = 0 \qquad Eq . ( 7 )$$

In Eq. (7),

$$\frac{\partial C}{\partial D [ i , j ]}$$

is the gradient of the cost with respect to the dose map. The adjustment of the values of D[i, j] can be determined using various gradient-based optimization methods, such as, for example, a gradient descent (or “steepest descent”) method, a conjugate gradient method, or any combination of any variant thereof.

At operation 510, when the predetermined condition is met, an optimized dose map can be outputted for use in multi-beam mask writing.

In the processes 300-500, the dose map can be optimized through co-optimization using the mask-making simulation and the substrate-manufacturing simulation. As shown in Eqs. (1)-(7), compared with OPC-based dose map optimization, the values of the mask pattern {(mxₙ, myₙ)} are used as intermediate optimization variables. In other words, in the OPC-based dose map optimization, the values of the mask pattern need to be explicitly determined as the basis of OPC, while in the methods and systems disclosed herein, the values of the mask pattern {(mxₙ, myₙ)} are implicitly determined and no OPC is needed in the dose map optimization, which can increase computation efficiency. Also, the mask patterns determined by {(mxₙ, myₙ)} are not restricted to Manhattan polygons, and can be in more flexible shapes (e.g., curvilinear shapes). In other words, in the methods and systems disclosed herein, natural and efficient handling of curvilinear mask shapes is an inherent feature. In addition, because the similarity value (e.g., the cost) is determined based on a direct comparison between the substrate pattern and the design pattern, the results of the dose map optimization can achieve higher accuracy.

As described above, it should be noted that all or a portion of the aspects of the disclosure described herein can be implemented using a general-purpose computer/processor with a computer program that, when executed, carries out any of the respective techniques, algorithms, and/or instructions described herein. In addition, or alternatively, for example, a special-purpose computer/processor, which can contain specialized hardware for carrying out any of the techniques, algorithms, or instructions described herein, can be utilized.

The implementations of apparatuses as described herein (and the algorithms, methods, instructions, etc., stored thereon and/or executed thereby) can be realized in hardware, software, or any combination thereof. The hardware can include, for example, computers, intellectual property (IP) cores, application-specific integrated circuits (ASICs), programmable logic arrays, optical processors, programmable logic controllers, microcode, microcontrollers, servers, microprocessors, digital signal processors, or any other suitable circuit. In the claims, the term “processor” should be understood as encompassing any of the foregoing, either singly or in combination. The terms “signal” and “data” are used interchangeably. Further, portions of the apparatuses do not necessarily have to be implemented in the same manner.

The aspects of the disclosure described herein can be described in terms of functional block components and various processing operations. The disclosed processes and sequences can be performed individually or in any combination. Functional blocks can be realized by any number of hardware and/or software components that perform the specified functions. For example, the described aspects can employ various integrated circuit components (e.g., memory elements, processing elements, logic elements, look-up tables, and the like), which can carry out a variety of functions under the control of one or more microprocessors or other control devices. Similarly, where the elements of the described aspects are implemented using software programming or software elements, the disclosure can be implemented with any programming or scripting languages, such as C, C++, Java, assembler, or the like, with the various algorithms being implemented with any combination of data structures, objects, processes, routines, or other programming elements. Functional aspects can be implemented in algorithms that execute on one or more processors. Furthermore, the aspects of the disclosure could employ any number of techniques for electronics configuration, signal processing and/or control, data processing, and the like. The words “mechanism” and “element” are used broadly and are not limited to mechanical or physical implementations or aspects, but can include software routines in conjunction with processors, etc.

Implementations or portions of implementations of the disclosure can take the form of a computer program product accessible from, for example, a computer-usable or computer-readable medium. A computer-usable or computer-readable medium can be any device that can, for example, tangibly contain, store, communicate, or transport a program or data structure for use by or in connection with any processor. The medium can be, for example, an electronic, magnetic, optical, electromagnetic, or semiconductor device, such as a hard disk drive, a memory device, a solid-state drive, a flash drive, or an optical drive. Other suitable mediums are also available. Such computer-usable or computer-readable media can be referred to as non-transitory memory or media. Unless otherwise specified, a memory of an apparatus described herein does not have to be physically contained in the apparatus, but can be a memory that can be accessed remotely by the apparatus, and does not have to be contiguous with other memory that might be physically contained by the apparatus.

Any of the individual or combined functions described herein as being performed as examples of the disclosure can be implemented using machine-readable instructions in the form of code for the operation of any or any combination of the aforementioned computational hardware. The computational code can be implemented in the form of one or more modules by which individual or combined functions can be performed as a computational tool, the input and output data of each module being passed to/from one or more further modules during operation of the methods, apparatuses, and systems described herein.

Information, data, and signals can be represented using a variety of different technologies and techniques. For example, any data, instructions, commands, information, signals, bits, symbols, and chips referenced herein can be represented by voltages, currents, electromagnetic waves, magnetic fields or particles, optical fields or particles, other items, or a combination of the foregoing.

The particular aspects shown and described herein are illustrative examples of the disclosure and are not intended to otherwise limit the scope of the disclosure in any way. For the sake of brevity, electronics, control systems, software development, and other functional aspects of the systems (and components of the individual operating components of the systems) cannot be described in detail herein. Furthermore, the connecting lines or connectors shown in the various figures presented are intended to represent exemplary functional relationships and/or physical or logical couplings between the various elements. Many alternative or additional functional relationships, physical connections, or logical connections can be present in a practical device.

The word “example” is used herein to mean serving as an example, instance, or illustration. Any aspect or design described herein as “example” is not necessarily to be construed as being preferred or advantageous over other aspects or designs. Rather, use of the word “example” is intended to present concepts in a concrete fashion. As used in this disclosure, the term “or” is intended to mean an inclusive “or” rather than an exclusive “or” for the two or more elements it conjoins. That is, unless specified otherwise or clearly indicated otherwise by the context, “X includes A or B” is intended to mean any of the natural inclusive permutations thereof. In other words, if X includes A; X includes B; or X includes both A and B, then “X includes A or B” is satisfied under any of the foregoing instances. The term “and/or” as used in this disclosure is intended to mean an “and” or an inclusive “or.” That is, unless specified otherwise or clearly indicated otherwise by the context, “X includes A, B, and/or C” is intended to mean that X can include any combinations of A, B, and C. In other words, if X includes A; X includes B; X includes C; X includes both A and B; X includes both B and C; X includes both A and C; or X includes all of A, B, and C, then “X includes A and/or B” is satisfied under any of the foregoing instances. Similarly, “X includes at least one of A, B, and C” is intended to be used as an equivalent of “X includes A, B, and/or C.” In addition, the articles “a” and “an” as used in this application and the appended claims should generally be construed to mean “one or more” unless specified otherwise or clear from context to be directed to a singular form. Moreover, use of the term “an aspect” or “one aspect” throughout this disclosure is not intended to mean the same aspect or implementation unless described as such.

The use of “including” or “having” and variations thereof herein is meant to encompass the items listed thereafter and equivalents thereof as well as additional items. Unless specified or limited otherwise, the terms “mounted,” “connected,” “supported,” “coupled,” and variations thereof are used broadly and encompass both direct and indirect mountings, connections, supports, and couplings. Further, “connected” and “coupled” are not restricted to physical or mechanical connections or couplings.

The use of the terms “a” and “an” and “the” and similar referents in the context of describing the disclosure (especially in the context of the following claims) should be construed to cover both the singular and the plural. Furthermore, recitation of ranges of values herein is merely intended to serve as a shorthand method of referring individually to each separate value falling within the range, unless otherwise indicated herein, and each separate value is incorporated into the specification as if it were individually recited herein. Finally, the operations of all methods described herein are performable in any suitable order unless otherwise indicated herein or otherwise clearly contradicted by the context. The use of any and all examples, or exemplary language (e.g., “such as”) provided herein, is intended merely to better illuminate the disclosure and does not pose a limitation on the scope of the disclosure unless otherwise claimed.

It should be understood that although this disclosure uses terms such as first, second, third, etc., the disclosure should not be limited to these terms. These terms are used only to distinguish similar types of information from each other. For example, without departing from the scope of this disclosure, a first information can also be referred to as a second information; and similarly, a second information can also be referred to as a first information. Depending on the context, the word “if” as used herein can be interpreted as “when,” “while,” or “in response to.”

While the disclosure has been described in connection with certain implementations, it is to be understood that the disclosure is not to be limited to the disclosed implementations but, on the contrary, is intended to cover various modifications and equivalent arrangements included within the scope of the appended claims, which scope is to be accorded the broadest interpretation as is permitted under the law so as to encompass all such modifications and equivalent arrangements.

What is claimed is:

1. A method for optimizing a dose map for a multi-beam mask writer, comprising:
simulating, by a processor, a substrate pattern based on a design pattern and the dose map associated with the design pattern; and
updating a value of the dose map based on a comparison between the substrate pattern and the design pattern.

2. The method of claim 1, wherein simulating the substrate pattern based on the design pattern and the dose map associated with the design pattern comprises:
simulating a mask pattern based on the design pattern and the dose map; and
simulating the substrate pattern based on the mask pattern.

3. The method of claim 2, wherein the mask pattern and the substrate pattern are pixelated.

4. The method of claim 1, wherein the value of the dose map comprises at least one of a coordinate of an e-beam shot associated with the dose map, an intensity value of the e-beam shot, an exposure time of the e-beam shot, and an energy exposure value of the e-beam shot.

5. The method of claim 1, wherein the comparison between the substrate pattern and the design pattern comprises a similarity value indicative of similarity between the substrate pattern and the design pattern.

6. The method of claim 5, wherein the similarity value is determined based on distances between points of the substrate pattern and respective corresponding points in the design pattern.

7. The method of claim 5, wherein updating the value of the dose map based on the comparison between the substrate pattern and the design pattern comprises:
based on a determination that the similarity value is greater than or equal to a predetermined threshold, updating the value of the dose map; and
based on a determination that the similarity value is smaller than the predetermined threshold, outputting the dose map for mask making.

8. An apparatus for optimizing a dose map for a multi-beam mask writer, comprising:
a processor; and
a memory coupled to the processor, the memory configured to store instructions which when executed by the processor become operational with the processor to:
simulate a substrate pattern based on a design pattern and the dose map associated with the design pattern; and
update a value of the dose map based on a comparison between the substrate pattern and the design pattern.

9. The apparatus of claim 8, wherein the memory storing the instructions operational with the processor to simulate the substrate pattern based on the design pattern and the dose map associated with the design pattern further comprises instructions which when executed by the processor become operational with the processor to:
simulate a mask pattern based on the design pattern and the dose map; and
simulate the substrate pattern based on the mask pattern.

10. The apparatus of claim 9, wherein the mask pattern and the substrate pattern are pixelated.

11. The apparatus of claim 8, wherein the value of the dose map comprises at least one of a coordinate of an e-beam shot associated with the dose map, an intensity value of the e-beam shot, an exposure time of the e-beam shot, and an energy exposure value of the e-beam shot.

12. The apparatus of claim 8, wherein the comparison between the substrate pattern and the design pattern comprises a similarity value indicative of similarity between the substrate pattern and the design pattern.

13. The apparatus of claim 12, wherein the similarity value is determined based on distances between points of the substrate pattern and respective corresponding points in the design pattern.

14. The apparatus of claim 12, wherein the memory storing the instructions operational with the processor to update the value of the dose map based on the comparison between the substrate pattern and the design pattern further comprises instructions which when executed by the processor become operational with the processor to:
based on a determination that the similarity value is greater than or equal to a predetermined threshold, update the value of the dose map; and
based on a determination that the similarity value is smaller than the predetermined threshold, output the dose map for mask making.

15. A non-transitory computer-readable storage medium, comprising instructions for optimizing a dose map for a multi-beam mask writer, which instructions when executed by a processor become operational with the processor to:
simulate a substrate pattern based on a design pattern and the dose map associated with the design pattern; and
update a value of the dose map based on a comparison between the substrate pattern and the design pattern.

16. The non-transitory computer-readable storage medium of claim 15, wherein the instructions operational with the processor to simulate the substrate pattern based on the design pattern and the dose map associated with the design pattern further comprise instructions which when executed by the processor become operational with the processor to:
simulate a mask pattern based on the design pattern and the dose map; and
simulate the substrate pattern based on the mask pattern.

17. The non-transitory computer-readable storage medium of claim 15, wherein the value of the dose map comprises at least one of a coordinate of an e-beam shot associated with the dose map, an intensity value of the e-beam shot, an exposure time of the e-beam shot, and an energy exposure value of the e-beam shot.

18. The non-transitory computer-readable storage medium of claim 15, wherein the comparison between the substrate pattern and the design pattern comprises a similarity value indicative of similarity between the substrate pattern and the design pattern.

19. The non-transitory computer-readable storage medium of claim 18, wherein the similarity value is determined based on distances between points of the substrate pattern and respective corresponding points in the design pattern.

20. The non-transitory computer-readable storage medium of claim 18, wherein the instructions operational with the processor to update the value of the dose map based on the comparison between the substrate pattern and the design pattern further comprise instructions which when executed by the processor become operational with the processor to:
based on a determination that the similarity value is greater than or equal to a predetermined threshold, update the value of the dose map; and
based on a determination that the similarity value is smaller than the predetermined threshold, output the dose map for mask making.
